(19) United States
(12) Patent Application Publication
(10) Pub. No.: US 2018/0166858 A1
(43) Pub. Date: Jun. 14, 2018

(54) QUANTUM CASCADE LASER

(71) Applicant: SUMITOMO ELECTRIC INDUSTRIES, LTD., Osaka (JP)

(72) Inventor: Jun-ichi HASHIMOTO, Yokohama-shi (JP)

(73) Assignee: SUMITOMO ELECTRIC INDUSTRIES, LTD., Osaka (JP)

(21) Appl. No.: 15/834,853

(22) Filed: Dec. 7, 2017

(30) Foreign Application Priority Data
Dec. 8, 2016 (JP) 2016-238725

(51) Int. Cl. H01S 5/34; H01S 5/026; H01S 5/028; H01S 5/227; H01S 5/042

(52) U.S. Cl. CPC H01S 5/3401; H01S 5/0261; H01S 5/0287; H01S 5/4031; H01S 5/2275; H01S 5/0425; H01S 5/2272

(57) ABSTRACT

A quantum cascade laser includes a laser structure including a substrate and a semiconductor laminate region, the substrate having a principal surface that includes first to third areas that extend in a direction of a first axis, the substrate having first and second end faces arranged in the direction of the first axis, the semiconductor laminate region having first and second mesas and a semiconductor mesa which are arranged on the first to third areas, respectively; and a first semiconductor film disposed on the third area, side faces of the first and second mesas, and an end face of the semiconductor mesa. The laser structure includes a first region including the semiconductor mesa, and a second region including the first and second mesas. The second region includes a recess defined by the third area, the side face of the first mesa, and the side face of the second mesa.

### BACKGROUND OF THE INVENTION

### Field of the Invention

The present invention relates to a quantum cascade laser. This application claims the benefit of priority from Japanese Patent application No. 2016-238725 filed on Dec. 8, 2016, which is herein incorporated by reference in its entirety.

### Related Background Art

Applied Physics Letters, vol. 83, pp. 1929-1931, 2003 discloses a mid-infrared quantum cascade semiconductor laser including a group III-V compound semiconductor material.

### SUMMARY OF THE INVENTION

A quantum cascade laser according to one aspect of the present invention includes a laser structure including a substrate and a semiconductor laminate region, the substrate having a principal surface that includes a first area, a second area, and a third area that extend in a direction of a first axis, the third area being disposed between the first area and the second area, the substrate having a first end face and a second end face which are arranged in the direction of the first axis, the semiconductor laminate region having a first mesa, a second mesa, and a semiconductor mesa which are arranged on the first area, the second area, and the third area, respectively; and a first semiconductor film disposed on the third area of the substrate, a side face of the first mesa, a side face of the second mesa, and an end face of the semiconductor mesa. The laser structure includes a first region and a second region arranged in the direction of the first axis, the first region including the semiconductor mesa, and the second region including the first mesa and the second mesa. The semiconductor mesa includes a core region. In addition, the second region of the laser structure includes a recess defined by the third area, the side face of the first mesa, and the side face of the second mesa.

### BRIEF DESCRIPTION OF THE DRAWINGS

The above-described objects and the other objects, features, and advantages of the present invention become more apparent from the following detailed description of the preferred embodiments of the present invention proceeding with reference to the attached drawings.

FIG. 1 is a plan view showing a quantum cascade laser according to the present embodiment.

FIG. 2 is a cross-sectional view taken along line II-II shown in FIG. 1.

FIG. 3 is a cross-sectional view taken along line III-III shown in FIG. 1.

FIG. 4 is a plan view showing a quantum cascade laser having a large spacing region.

FIG. 5 is a cross-sectional view taken along line V-V shown in FIG. 4.

FIG. 6 is a plan view showing a quantum cascade laser according to the present embodiment.

FIG. 7 is a cross-sectional view taken along line VII-VII shown in FIG. 6.

FIG. 8 is a plan view showing the quantum cascade semiconductor laser according to the embodiment.

FIG. 9 is a view showing a cross section taken along line IX-IX shown in FIG. 8.

FIG. 10 is a cross-sectional view taken along line X-X shown in FIG. 8.

FIG. 11 is a plan view showing a quantum cascade laser according to the present embodiment.

FIG. 12 is a cross-sectional view taken along line XII-XII shown in FIG. 11.

FIG. 13 is a cross-sectional view taken along line XIII-XIII shown in FIG. 11.

### DESCRIPTION OF THE EMBODIMENTS

A wafer is prepared to form multiple quantum cascade semiconductor lasers thereon through the following process steps, such as, epitaxial growth, etching process, and metallization, in the former half of the manufacturing process. In order to protect the end face of a core layer for light emission in each of the quantum cascade lasers, the end face of the semiconductor mesa including the core layer is covered with a protective layer, which is grown on the wafer. The protective layer prevents the end face of the core layer from being exposed to the atmosphere. Such a protective layer is formed not only on the end face of the semiconductor mesa but also on separation lines defining the arrangement of sections, each of which is prepared for a semiconductor chip. In the latter half of the manufacturing process, the wafer is divided along a separation line by a technique such as cleavage.

Inventor's findings reveal that dividing the wafer into the individual chips for semiconductor devices by a separating method, such as cleaving, applies force to the protective layer on the wafer, and such force may form defects, such as chipping and cracks, in the protective layer. These defects may extend inwardly from the outer edge of the device to the vicinity of the end face of the semiconductor mesa. In order to prevent the defects from reaching the vicinity of the end face of the semiconductor mesa in a quantum cascade semiconductor laser, the quantum cascade laser is provided with an isolation region that spaces the separation line apart from the end face of the semiconductor mesa, which is disposed in the inner region.

Specific embodiments according to the present above aspect will be described below.

A quantum cascade laser according to an embodiment includes (a) a laser structure including a substrate and a semiconductor laminate region, the substrate having a principal surface that includes a first area, a second area, and a third area that extend in a direction of a first axis, the third area being disposed between the first area and the second area, the substrate having a first end face and a second end face which are arranged in the direction of the first axis, the semiconductor laminate region having a first mesa, a second mesa, and a semiconductor mesa which are arranged on the first area, the second area, and the third area, respectively; and (b) a first semiconductor film disposed on the third area of the substrate, a side face of the first mesa, a side face of the second mesa, and an end face of the semiconductor mesa. The laser structure includes a first region and a second region arranged in the direction of the first axis, the first region including the semiconductor mesa, and the second region including the first mesa and the second mesa. The semiconductor mesa includes a core region. In addition, the second region of the laser structure includes a recess defined by the third area, the side face of the first mesa, and the side face of the second mesa.

The quantum cascade laser has the first semiconductor film that is disposed on not only the third area and the end face of the semiconductor mesa but also side faces of the first mesa and the second mesa. This structure allows the first and second mesas at both side edges of the third area to support the first semiconductor film on the third area, and further allows the first semiconductor film to make contact with the side faces, made of semiconductor, of the first mesa and the second mesa.

In the quantum cascade laser according to an embodiment, preferably, the first region includes the first mesa and the second mesa. The semiconductor mesa is disposed between the first mesa and the second mesa. In the first region, the semiconductor mesa is separated from the side face of the first mesa and the side face of the second mesa.

The quantum cascade laser provides each of the first and second regions of the laser structure with the first and first mesas. The first and second mesas are arranged in not only the first region but also the second region, and the arrangement of the first and second mesas in the first and second regions makes it possible to form the laser structure, which includes a limited area(s) isolated by the above arrangement, by etching. The limitation in the etching area(s) is effective in increasing the etching rate. The increased etching rate makes it easy to form a high semiconductor mesa needed for the quantum cascade laser, shortens the etching time, and enhances the productivity. In addition, providing the first and second regions with the first and second mesas enables epi-down mounting.

The quantum cascade laser according to an embodiment may further include an insulating film disposed on the first semiconductor film.

The quantum cascade laser including the insulating film can reduce the occurrence of the peeling and/or cracking of the first semiconductor film in producing a semiconductor chip, for example, by cleavage, and the breakage of the first semiconductor film covering the end face of the semiconductor mesa is less likely to occur.

The quantum cascade laser according to an embodiment may further include a reflective film disposed on the first semiconductor film disposed on the end face of the semiconductor mesa.

The quantum cascade laser including the light reflective film on the end face of the semiconductor mesa can improve light reflectance thereat.

In the quantum cascade laser according to an embodiment, the reflective film may include gold.

The application of Au-based material to the quantum cascade laser provides the quantum cascade semiconductor laser with high reflectance in the lasing wavelengths.

The quantum cascade laser according to an embodiment may further include an electrode on the first region, the electrode including the same material as that of the reflective film.

In the quantum cascade laser, the electrode and the reflective film that include the same material may be formed in the same process together

In the quantum cascade laser according to an embodiment, preferably, the first semiconductor film is disposed on side faces of the semiconductor mesa. The semiconductor mesa and the first semiconductor film constitute a waveguide mesa. The laser structure has a first recess and a second recess in the first region. The first recess separates the waveguide mesa from the first mesa. In addition, the second recess separates the waveguide mesa from the second mesa.

In the quantum cascade laser, both the end faces and side faces of the semiconductor mesa are covered with the first semiconductor film continuously. The first semiconductor film on the end and side faces of the semiconductor mesa works as a current blocking layer. The first semiconductor film is formed on both the end face of the semiconductor mesa and the side faces of the semiconductor mesa in the same process simultaneously. Further, each of the first and second regions of the laser structure includes the first mesa and the second mesa. The arrangement of the first and second mesas in the second region is provided in addition to the first region to allow forming the laser structure by etching of a limited area(s), such as the recess, the first recess and the second recess. Such a limited area(s) in etching can alleviate the difficulty in forming the laser structure thereby.

Teachings of the present invention can be readily understood by considering the following detailed description with reference to the accompanying drawings shown as examples. Referring to the accompanying drawings, embodiments of a quantum cascade laser, and a method for fabricating a quantum cascade laser according to the present invention will be described below. To facilitate understanding, identical reference numerals are used, where possible, to designate identical elements that are common to the figures.

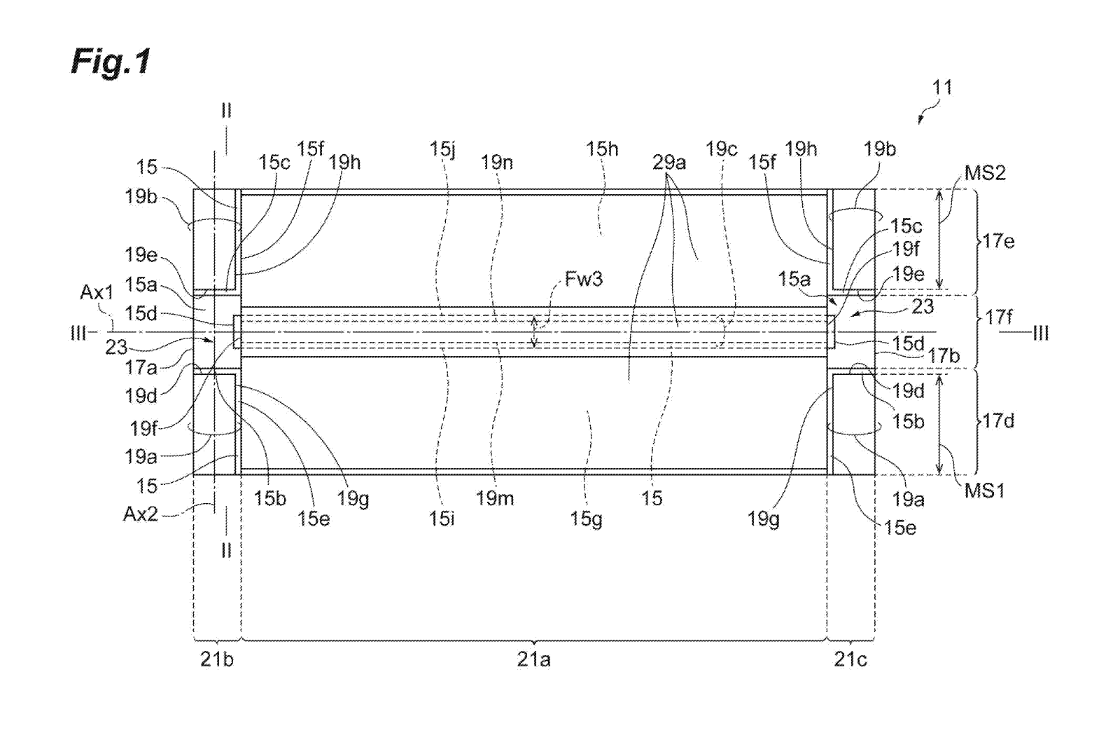

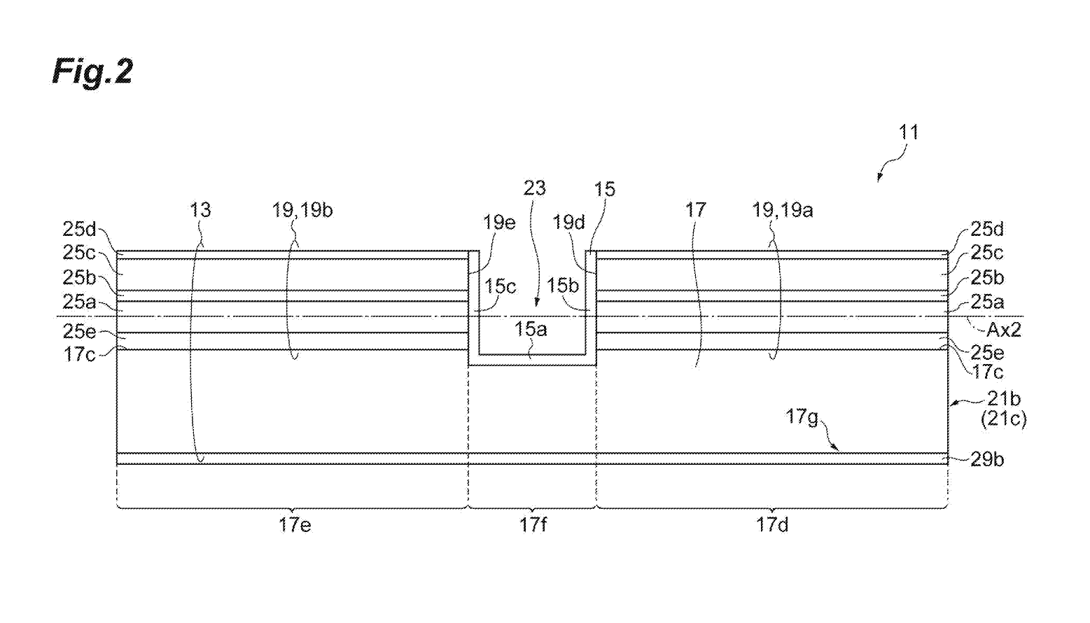

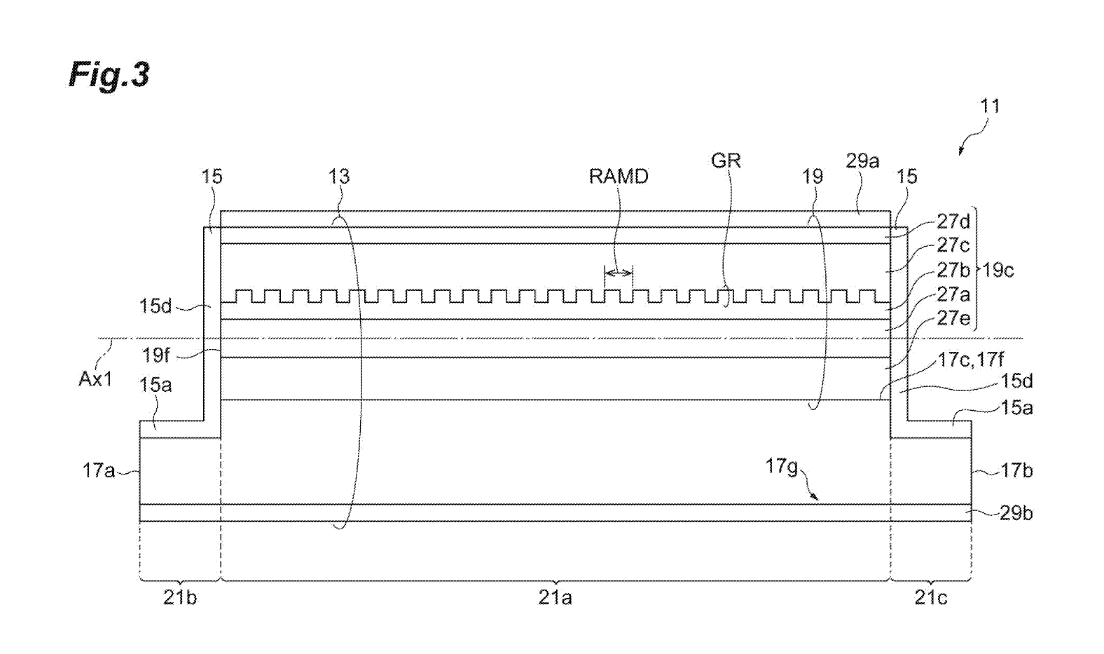

FIG. 1 is a plan view showing a quantum cascade laser according to an embodiment. FIG. 2 is a cross-sectional view taken along line II-II shown in FIG. 1. FIG. 3 is a cross-sectional view taken along line III-III shown in FIG. 1.

### First Embodiment

With reference to FIGS. 1 to 3, the quantum cascade laser 11 according to the first embodiment will be described below. The quantum cascade laser 11 includes a laser structure 13 and a first semiconductor film 15. The laser structure 13 includes a substrate 17 and a semiconductor laminate region 19. The substrate 17 includes a first end face 17a, a second end face 17b, and a principal surface 17c. The first and second end faces 17a and 17b are arranged in a direction of a first axis Ax1. The principal surface 17 c includes a first area 17d, a second area 17e, and a third area 17f. The first area 17d, the second area 17e, and the third area 17f extend in a direction of a second axis Ax2 intersecting the first axis Ax1, and the third area 17f is disposed between the first area 17d and the second area 17e. In the present embodiment, the third area 17f is in contact with the first area 17d and the second area 17e. The first semiconductor film 15 makes contact with the underlying semiconductor region. The first semiconductor film 15 includes at least one of an undoped semiconductor and a semi-insulating semiconductor.

The semiconductor laminate region 19 includes a first mesa 19a, a second mesa 19b, and a semiconductor mesa 19c. The undoped and semi-insulating semiconductors which are in contact with the end face 19f of the semiconductor mesa 19c can reduce a leakage current flowing via the interface between the end face 19f and the first semiconductor film 15. Preferably, the first semiconductor film 15 includes at least one of InP and InGaAsP, which contain no aluminum as a constituent element and therefore can avoid deterioration of the end face caused by the oxidation of aluminum. The first and second mesas 19a and 19b are disposed on the first and second area 17d and 17e, respectively. The semiconductor mesa 19c is disposed on the third area 17f.

The first semiconductor film 15 includes a first portion 15a, a second portion 15b, a third portion 15c, and a fourth portion 15d. The first portion 15a is disposed on the third area 17f of the substrate 17, and the second portion 15b and the third portion 15c are disposed on the first side face 19d of the first mesa 19a and the second side face 19e of the second mesa 19b, respectively. The fourth portion 15d is disposed on the end face 19f of the semiconductor mesa 19c.

The semiconductor laminate region 19 includes a first region 21a, a second region 21b, and a third region 21c. The first region 21a, the second region 21b, and the third region 21c are arranged in the direction of the first axis Ax1. The first region 21a is disposed between the second and third regions 21b and 21c. The first region 21a includes a semiconductor mesa 19c, and the second region 21b includes the first and second mesas 19a and 19b. The second region 21b has a recess 23, which is defined by the third area 17f, the first side face 19d of the first mesa 19a, and the second side face 19e of the second mesa 19b. The first and second side faces 19d and 19e extend in the direction of the first axis Ax1, and accordingly the recess 23 also extends in the direction of the first axis Ax1. In the present embodiment, the third region 21c has substantially the same structure as the second region 21b, and the subsequent description will be made with reference to the second region 21b.

In the method for fabricating the quantum cascade laser 11, a substrate product that includes the arrangement of sections each of which is prepared for the quantum cascade laser 11, and are separated to produce individual semiconductor chips from the arrangement of sections. In forming the semiconductor chips, the semiconductor thin layer for the first semiconductor film 15 is separated into the individual chips. This separating uses force, which is applied to the semiconductor thin layer. In the quantum cascade laser 11, the first semiconductor film 15 is, however, provided on not only the third area 17f and the end face 19f of the semiconductor mesa 19c but also both the first side face 19d of the first mesa 19a and the second side face 19e of the second mesa 19b. The first semiconductor film 15 extends to the semiconductor side faces (19d and 19e) of the first and second mesas 19a and 19b, and makes contact with the side faces (19d and 19e). The first semiconductor film 15 on the first and second mesas 19a and 19b can support the first semiconductor film 15 on the third area 17f on both side edges of the third area 17f. Preferably, the first and second mesas 19a and 19b each have a height of 5 micrometers or more. The first and second mesas 19a and 19b have width MS1 and MS2, respectively, which are larger than the width Fw3 of the first semiconductor film 15 covering the third area 17f.

The quantum cascade semiconductor laser 11 has a structure that can reduce the probability of propagation of defects, which may be introduced into the semiconductor thin layer (a semiconductor thin layer prepared for the first semiconductor film 15) at the breakage, for example, cleavage, caused to form the end faces (17a and 17b) in producing individual chips, toward the interior of the device.

The first semiconductor film 15 further includes a fifth portion 15e, a sixth portion 15f, a seventh portion 15g, an eighth portion 15h, a ninth portion 15i, and a tenth portion 15j. The first mesa 19a and the second mesa 19b include a third side face 19g and a fourth side face 19h, respectively, each of which extends along a reference plane intersecting the first axis Ax1. The fifth and sixth portions 15e and 15f are disposed on the third and fourth side faces 19g and 19h, respectively. The fifth portion 15e, which is located on the third side face 19g of the first mesa 19a in the second region 21b, is connected to the seventh portion 15g, which is located on the first area 17d and reaches the fifth portion 15e on the third side face 19g of the first mesa 19a in the third region 21c. The sixth portion 15f, which is located on the fourth side face 19h of the second mesa 19b in the second region 21b, is connected to the eighth portion 15h, which is located on the second area 17e and reaches the sixth portion 15f on the fourth side face 19h of the second mesa 19b in the third region 21c.

The semiconductor mesa 19c has a fifth side face 19m and a sixth side face 19n, which extend in the direction of the first axis Ax1. The ninth portion 15i and the tenth portion 15j cover the fifth side face 19m and the sixth side face 19n, respectively. The seventh portion 15g on the first area 17d extends on the third area 17f in the direction of the second axis Ax2 to reach the ninth portion 15i on the fifth side surface 19m. The eighth portion 15h on the second area 17e extends on the third area 17f in the direction of the second axis Ax2 to reach the tenth portion 15j on the sixth side face 19n. The ninth portion 15i and the tenth portion 15j are connected to the fourth portion 15d on the end face 19f. The seventh and eighth portions 15g and 15h on the third area 17f are connected to the first portion 15a.

The semiconductor laminate region 19 includes a first semiconductor layer 25a for the core layer 27a, a second semiconductor layer 25b for the diffraction grating layer 27b, a third semiconductor layer 25c for the upper cladding layer 27c, a fourth semiconductor layer 25d for the contact layer 27d, and a fifth semiconductor layer 25e for the lower cladding layer 27e. Specifically, the first mesa 19a and the second mesa 19b each include the first semiconductor layer 25a, the second semiconductor layer 25b, the third semiconductor layer 25c, the fourth semiconductor layer 25d, and the fifth semiconductor layer 25e, and the semiconductor mesa 19c includes the core layer 27a, the diffraction grating layer 27b, the upper cladding layer 27c, the contact layer 27d, and the lower cladding layer 27e. In the present embodiment, the first and second mesas 19a and 19 b and the semiconductor mesa 19c have the same laminate structure.

In the quantum cascade semiconductor laser 11, the diffraction grating layer 27b and the upper cladding layer 27c form an interface therebetween, which constitutes a diffraction grating GR that provides a periodic refractive index change. The quantum cascade semiconductor laser 11 has a first electrode 29a disposed on the contact layer 27d, and specifically, makes contact with the upper face of the semiconductor mesa 19c. The quantum cascade semiconductor laser 11 includes a second electrode 29b, which is in contact with the rear surface 17g of the substrate 17. In the present embodiment, the first electrode 29a is disposed on the fifth and sixth side faces 19m and 19n of the semiconductor mesa 19c, and receives heat from the semiconductor mesa 19c. In addition, the first electrode 29a may extend toward the lower ends of the fifth and sixth side faces 19m and 19n, and further may be disposed on the principal surface 17c of the substrate 17. The first electrode 29a is disposed on the first and second areas 17d and 17e to enable the dissipation of heat from the semiconductor mesa 19c. If necessary, an insulating layer can be disposed between the first electrode 29a and the first semiconductor film 15. The insulating layer may include, for example, silicon based inorganic insulator and/or other inorganic film, and the silicon based inorganic insulating material includes silicon oxide, silicon nitride, and silicon oxynitride.

### Example

As shown in FIGS. 1, 2 and 3, the main body region, which is disposed in the central region of the device, includes a mesa waveguide structure available for laser oscillation, and is disposed between external regions, which are contiguous to respective end portions of the main body region. The main body region has a buried heterostructure. Both ends of the semiconductor mesa 19c are provided with respective mirror structures for the optical cavity. In the present embodiment, the first semiconductor film 15d on the end face 19f of the semiconductor mesa 19c works as an end facet of the laser cavity. The first semiconductor film 15d is formed on the end face 19f, made of semiconductor, of the mesa waveguide structure. The first semiconductor film 15 is also disposed on the side faces of the first and second mesas 19a and 19b, which are located in the outer region, and is supported by the first and second mesas 19a and 19b.

The substrate 17 may include, for example, a semiconductor substrate, which can be, for example, an n-type InP substrate. The substrate 17 is electrically conductive. Semiconductor layers constituting the mid-infrared quantum cascade semiconductor laser each have a lattice constant close to or equal to that of an InP semiconductor, and the InP substrate can provide excellent crystal qualities in growing these semiconductor layers for the lower cladding layer 27e, the core layer 27a, the diffraction grating layer 27b, the upper cladding layer 27c, and the contact layer 27d. The semiconductor layers can be grown by, for example, metal organic vapor phase epitaxy or molecular beam epitaxy. InP is transparent to lasing light of mid-infrared wavelengths. The InP substrate 17 can be used for the lower cladding region.

The lower and upper cladding layers 27e and 27c may include, for example, n-type InP, which can transmit lasing light in mid-infrared wavelengths, and InP is a binary mixed crystal, and is lattice-matched to InP of the substrate. The lower cladding layer 27e made of InP can provide a base enabling good crystal growth of the core layer. The cladding layer of InP ensures the good radiation of heat from the core layer in terms of thermal conductivity. If the substrate 17 is made of a material transparent to laser radiation, such as InP, it can be used as a lower cladding, and then, the lower cladding layer 27e is optional.

The core layer 27a for quantum cascade has a structure including multiple stages (for example, several tens of periods) of unit structures, each of which includes an active layer and an injection layer. The active and injection layers each have a superlattice structure, which includes barrier layers and quantum well layers alternately stacked. The superlattice structure includes a thin film having a thickness of several nanometers for the quantum well layers, and a thin-film having a thickness of several nanometers for the barrier layers, and the barrier layers each have a larger bandgap than bandgaps of the quantum well layers. Quantum cascade laser uses a single polarity carrier, for example, electron. Light is generated by a transition from the upper level of the electronic subband of the conduction band in an active layer of the core layer to the lower level. The difference in energy level of the electronic subband is suitable for emission of mid-infrared light. The light thus generated propagates in the semiconductor mesa, and is amplified by the optical cavity to laser oscillation.

Exemplary material of the quantum well layers: GaInAs or GaInAsP.
Exemplary material of the barrier layers: AlInAs.

The diffraction grating layer 27b can provide the quantum cascade laser with a distributed feedback structure. The diffraction grating extends in the direction of the first axis Ax1, and the diffraction grating structure is formed by photolithography and etching. The Bragg wavelength is defined by the period, RAMD, of the diffraction grating shown in FIG. 3, and the diffraction grating selectively reflects light of the Bragg wavelength, which is amplified in the optical cavity. This structure enables single mode oscillation. The diffraction grating uses semiconductor material of a high refractive index, such as undoped or n-type GaInAs, and such a semiconductor material allows the diffraction grating to have a large coupling coefficient.

The contact layer 27d can provides a good ohmic contact to the upper electrode. The contact layer 27d may include, for example, n-type GaInAs, which has a low bandgap and is lattice-matched to InP. The contact layer 27d is optional.

The first semiconductor film 15 on the end face of the waveguide structure can prevent the oxidation of constituent element of the semiconductor of the waveguide structure from occurring to avoid degradation of the end face. In order to prevent the first semiconductor film 15 from absorbing the laser light due to inter-band transition from the material thereof, the first semiconductor film 15 is formed of a semiconductor material having a higher bandgap energy than the photon energy of lasing light from the core layer 27a. The first semiconductor film 15 is made of semiconductor material having a high specific resistance to prevent a leakage current from flowing through the protective layer on the end face in operation of the quantum cascade semiconductor laser. Specifically, the first semiconductor film 15 may include an undoped or semi-insulating semiconductor, and may include, for example, an Fe-doped semiconductor. In order to avoid oxidation of the first semiconductor film 15 itself, the first semiconductor film 15 is made of a group III-V compound semiconductor containing no aluminum as a constituent element, such as InP or GaInAsP. The addition of a transition metal (e.g., Fe) to InP and GaInAsP makes them highly resistive. InP exhibits a high thermal conductivity, and can avoid deterioration in the dissipation of heat caused by the coating of the end faces 19f of the semiconductor mesa 19c and/or local rise in temperature at the end faces. The first semiconductor film 15 has a film thickness, for example, in the range of 0.5 to 10 micrometers, which is defined on the third area 17f of the second region 21b.

The first semiconductor film 15 is in contact with the underlying semiconductor region. The first semiconductor film 15 includes at least one of an undoped semiconductor and a semi-insulating semiconductor. The first semiconductor film 15d, which is made of undoped and semi-insulating semiconductors and is in contact with the end face 19f of the semiconductor mesa 19c, can reduce a leakage current that flows via the interface between the end face 19f and the first semiconductor film 15d. In addition, the undoped and semi-insulating semiconductors each have a low carrier concentration, which avoids optical absorption caused by free carriers therein.

The first semiconductor film 15 extends from the end faces (17a and/or 17b) of the substrate 17 over the third area 17f of the principal surface 17c of the substrate 17, and reaches the bottom of the end face of the semiconductor mesa 19c. The first semiconductor film 15 is also disposed on the side faces of the first and second mesas 19a and 19 b. The first semiconductor film 15 on the third area 17f is in contact with not only the principal surface 17c of the substrate 17 but also the side faces of the first and second mesas 19a and 19b. In such a structure, the first semiconductor film 15 can be reinforced by the semiconductor faces (17f, 19d, and 19e) extending in two different directions. The first and second mesas 19a and 19b enabling the reinforcement may include the same laminate structure as that of the semiconductor mesa 19c.

The current blocking layer is disposed on the side faces of the semiconductor mesa 19c, and in the present embodiment, may include the first semiconductor film 15. The first semiconductor film 15, which is disposed on the side faces of the semiconductor mesa 19c, can confine current into the semiconductor mesa 19c. The current blocking layer includes a high resistance semiconductor, which may be, for example, an undoped or semi-insulating semiconductor. Preferably, the high resistance semiconductor can be a semi-insulating semiconductor, which is provided by adding transition metal (for example, Fe, Ti, Cr, and Co) to a III-V group compound semiconductor, which is lattice-matched to InP. Fe-doped InP can provide the semiconductor with a high resistivity of, for example, 10⁵ Ωcm or more to electron (where “Ω” represents ohm in electrical unit), and works as a current blocking layer well. If possible, undoped semiconductor can be used to the current blocking layer. Exemplary material of current blocking layer (the first semiconductor film 15): undoped or semi-insulating InP, GaInAsP, AlGaInAs, AlInAs, and GaInAs.

In the following description, the current blocking layer may include the same semiconductor material as the first semiconductor film 15. The current blocking layer and the first semiconductor film 15 are simultaneously formed in the same film forming step. The simultaneous formation can simplify the manufacturing process and results in improvement in productivity and reduction in production cost.

In the first region 21a, an insulating film is provided between the first electrode 29a and the first semiconductor film 15. This insulating film can include a dielectric insulating film, such as SiO₂, SiON, SiN, alumina, benzocyclobutene (referred to as BCB), and polyimide. These films can be formed by a film formation method, such as sputtering, chemical vapor deposition (CVD), and spin coating. The insulating film is optional.

The first electrode 29a and the second electrode 29b each may include a metal laminate, such as Ti/Au, Ti/Pt/Au, or Ge/Au.

If necessary, between the core layer 27a and the diffraction grating layer 27b and/or between the core layer 27a and the lower cladding layer 27e, an optical confinement region may be provided. The addition of the light confinement region enhances the confinement of propagating light into the core region. The optical confinement region is made of a semiconductor material, which has a refractive index higher than that of the cladding layer and is, preferably, a material lattice matched to InP. The optical confinement region as above may include, for example, undoped or n-type GaInAs.

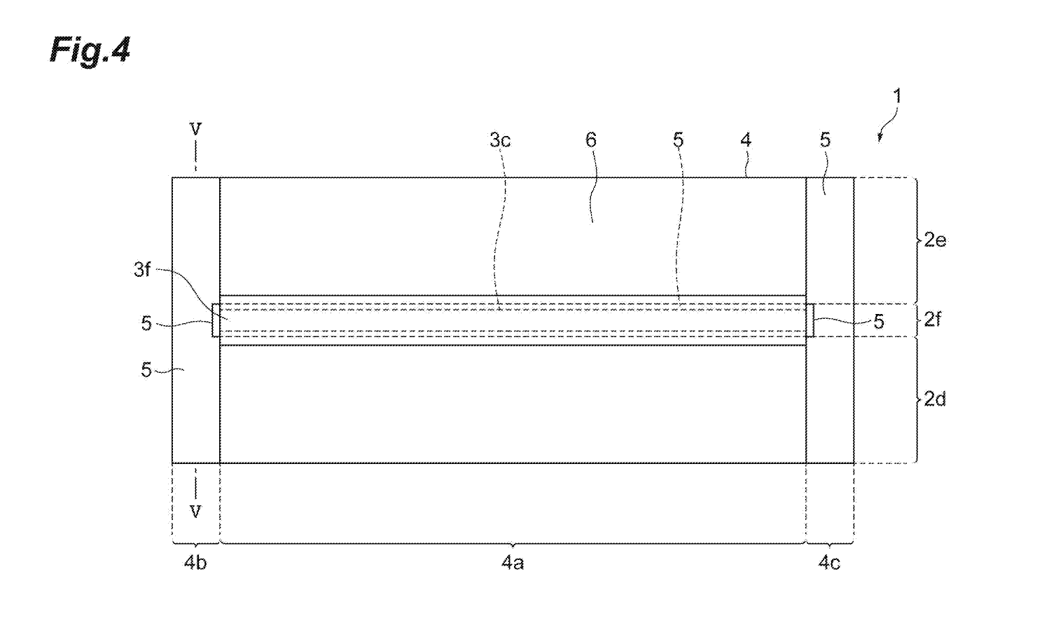

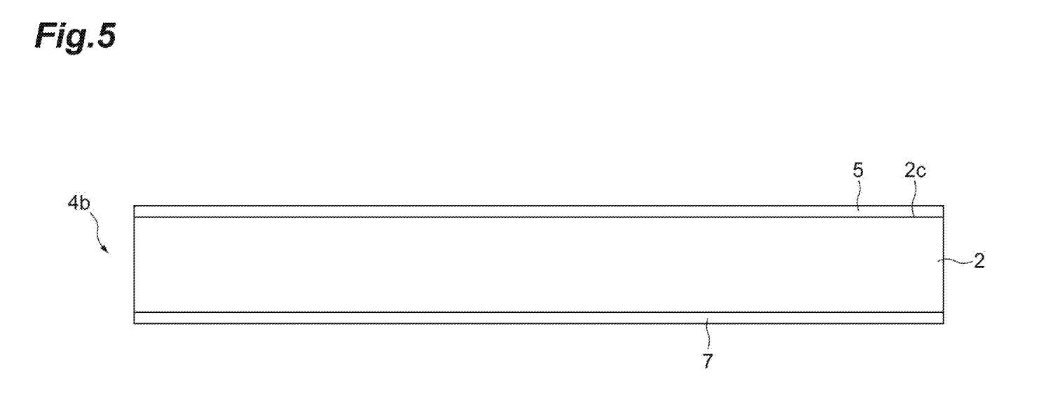

FIG. 4 is a view showing the structure of a quantum cascade semiconductor laser 1, which does not include the first mesa 19a and the second mesa 19b that the quantum cascade semiconductor laser shown in FIG. 1 include in the second region 21b and the third region 21c. FIG. 5 is a cross sectional view taken along line V-V shown in FIG. 4. In the quantum cascade semiconductor laser 1, the principal surface 2c of the substrate 2 includes a first area 2d, a second area 2e, and a third area 2f. The laser structure 4 includes a first region 4a, a second region 4b, and a third region 4c. The first region 4a, the second region 4b, and the third region 4c are arranged in one direction. The first region 4a is provided between the second region 4b and the third region 4c. As seen from the above description, the first region 4a includes the semiconductor mesa 3c, but the second region 4b and the third region 4c do not include any first and second mesas. The semiconductor mesa 3c has a mesa end face 3f covered with an end face film 5 made of a compound semiconductor. The principal surface 2c of the substrate 2 in the second region 4b and the third region 4c is covered with a flat end face film 5. This end face film 5 includes, for example, InP or InGaAsP, and has a film thickness in a range of, for example, 0.5 to 10 micrometers, which is defined as that on the second region 4b. The quantum cascade semiconductor laser 1 has an upper electrode 6 provided in a first region 4a. The laser structure 4 is provided under the upper electrode 6, and the upper electrode 6 makes contact with the semiconductor mesa 3c. On the back face of the substrate 2, a lower electrode 7 is provided.

The end face film 5, made of a thin film, is weak in mechanical strength, and in separating the wafer for the individual quantum cascade semiconductor laser 1 along a dividing line, for example, by using cleavage, the device thus produced may be subject to damage from the separation, so that defects, such as chipping and cracks, are likely to occur in the end face film 5 on the separation line, and such defects may extend from the edge of the device toward the end face 3f of the semiconductor mesa 3c, and result in cracks in the end face film 5 on the mesa end face 3f of the semiconductor mesa 3c.

The quantum cascade semiconductor laser 11 has a structure in which, in order to prevent the application of force in the dividing step, such as cleavage, to the article along a dividing line in the fabrication of the quantum cascade semiconductor laser 11 from forming defects in the first semiconductor film 15d on the mesa end face 19f of the semiconductor mesa 19c, the first mesa 19a (the second mesa 19b) is located at the first end face 17a (the second end face 17b), the edge of which is formed on and extends along a dividing line, and the semiconductor mesa 19 is apart from the above edge. The structure can prevent the defects generated at the division from reaching the first semiconductor film 15 on the semiconductor mesa 19, thereby avoiding the breakage of the first semiconductor film 15d, and does not have to make a distance between the first end face 17a (the second end face 17b) and the mesa end face 19f large. The structure allows the quantum cascade semiconductor laser 11 to have a distance, which is taken from the end face 19f of the semiconductor mesa 19c to the first end face 17a (the second end face 17b) in the direction of the first axis Ax1, of about 5 micrometers or less. This reduction can make the device small in size, thereby increasing the chip yield from the wafer, and reducing the production cost.

The quantum cascade semiconductor laser 11 of the present embodiment includes the first and second mesas 19a and 19 b. The first and second mesas 19a and 19b, which has the same laminate structure (the same thickness) as the semiconductor mesa 19c, support the first semiconductor film 15. Not only the first semiconductor film 15 but also the first and second mesas 19a and 19b, each of which has a large thickness and is in contact with the first semiconductor film 15, receive a cleavage force in the cleavage process. In addition, the first and second mesas 19a and 19b each having a large width as compared to the width of the first semiconductor film 15, which are defined as a width taken in the direction of the second axis Ax2 on the third area 17f, so that the first and second mesas 19a and 19b receives most of the cleavage force. Further, the addition of the first and second mesa 19a and 19b allows the first semiconductor film 15 on the third area 17f to have a smaller width, defined as a length taken in the direction of the second axis Ax2, than the width of the quantum cascade laser 11. The first semiconductor film 15 has an edge which extends in a part of the width of the chip in the direction of the second axis Ax2, and is apart from the sides of the chip at the edge.

### Second Embodiment

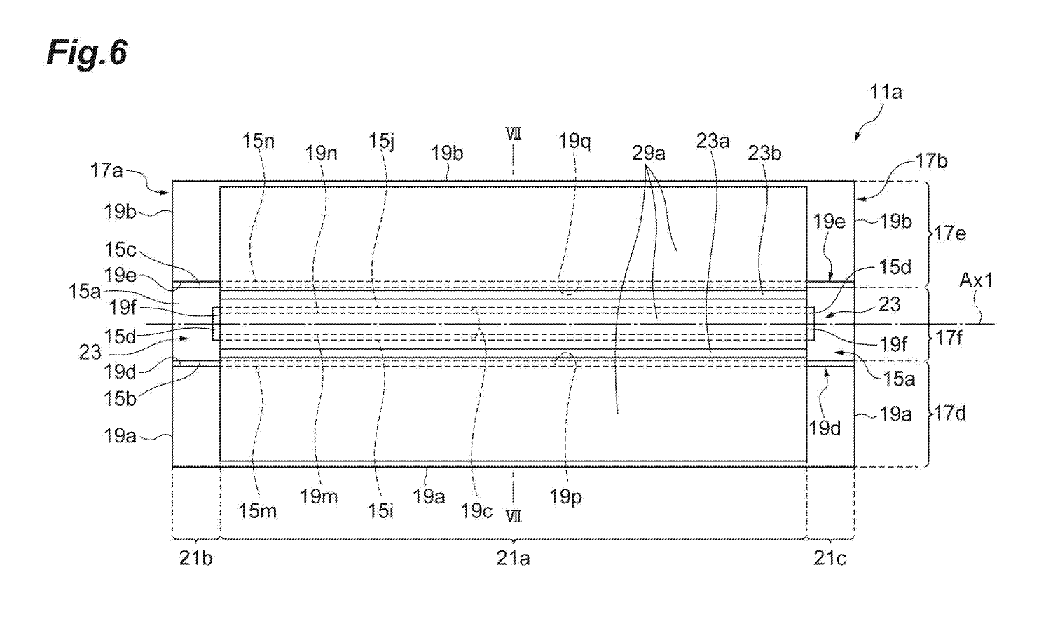

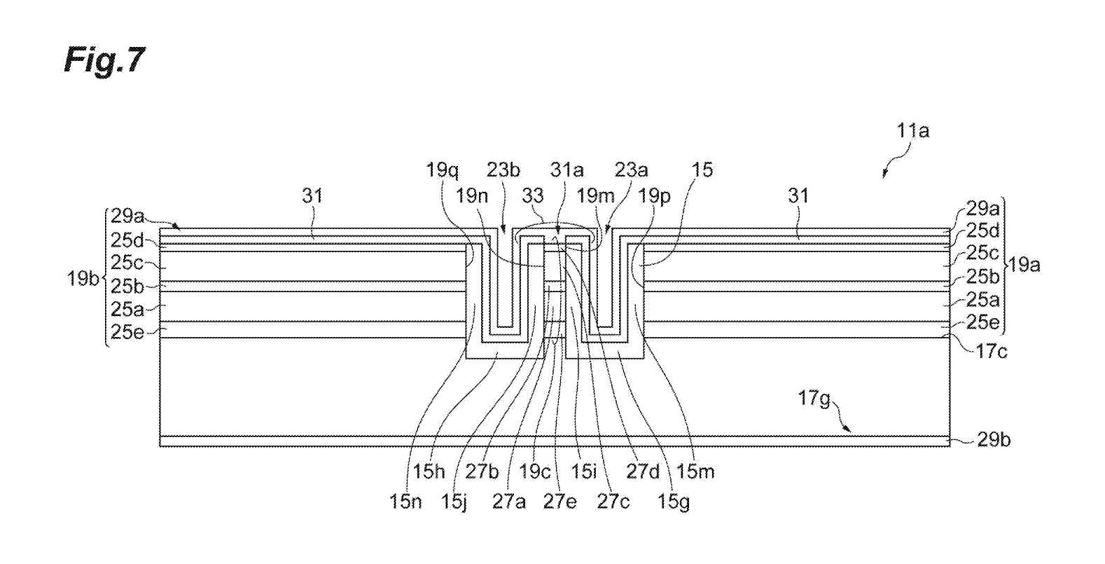

FIG. 6 is a plan view showing a quantum cascade semiconductor laser according to the embodiment. FIG. 7 is a cross-sectional view taken along line VII-VII shown in FIG. 6.

Referring to FIGS. 6 and 7, the quantum cascade semiconductor laser 11a according to the second embodiment will be described below. In the quantum cascade semiconductor laser 11a, the first region 21a includes the first mesa 19a and the second mesa 19b, which extend continuously from the second region 21b and the third region 21c to the first region 21a. The quantum cascade semiconductor laser 11a is different from the quantum cascade semiconductor laser 11 in terms of the arrangement of the first and second mesas 19a and 19b. In the quantum cascade semiconductor laser 11a, the semiconductor mesa 19c is located between the first mesa 19a and the second mesa 19b in the first region 21a. The semiconductor mesa 19c is separated from the seventh side face 19p of the first mesa 19a and the eighth side face 19q of the second mesa 19b. The seventh and eighth side faces 19p and 19q extend in the direction of the first axis Ax1.

The quantum cascade semiconductor laser 11a provides each of the first to third regions 21a, 21b, and 21c of the laser structure 13 with the first mesa 19a and the second mesa 19b. The first and second mesas 19a and 19b are arranged in not only the second and third regions 21b and 21c but also the first region 21a, and using the arrangement in the device allows the fabrication of the laser structure 13 to apply etching to a limited area in the mesa-etching process. The mesa etching of the limited area can enhance the etching rate. The enhanced etching rate makes it easy to form the semiconductor mesa 19c of a large height needed for the quantum cascade laser, and can shorten the etching time and improve the productivity. Further, the first and second mesas 19a and 19b is arranged in the first, second, and third regions 21a, 21b, and 21c, and this arrangement can prevent the device from having the protruding semiconductor mesa 19c in mounting the device in an epi-down manner. The first and second mesas 19a and 19b thus arranged can disperse the force, applied in the die-bonding process to the semiconductor mesa 19c, to the first mesa 19a and the second mesa 19b in mounting the device in an epi-down manner to avoid the breakage of the device, which is caused by concentration of the above force on the semiconductor mesa 19c. This structure allows the mounting in an epi-down manner in high yield.

The quantum cascade semiconductor laser 11a further includes an insulating film 31 disposed between the first electrode 29a and the first semiconductor film 15. The insulating film 31 covers and protects the first semiconductor film 15, and the addition of the insulating film 31 reinforces the first semiconductor film 15 in mechanical strength. In the first region 21a, the insulating film 31 is disposed on the surface (upper and side faces) of the first mesa 19a, on the surface (upper and side faces) of the second mesa 19b, and on the side faces of the semiconductor mesa 19c, and has an opening 31a on the top face of the semiconductor mesa 19c. Specifically, in the first region 21a, the insulating film 31 covers the top face of the first and second mesas 19a and 19b, the first semiconductor film 15 on the side faces of the first and second mesas 19a and 19b, and the first semiconductor film 15 on the third area 17f.

Each of the first and second mesas 19a and 19b has a seventh side face 19p and an eighth side face 19q in the first region 21a. The seventh and eighth side faces 19p and 19q extend in the direction of the first axis Ax1.

The quantum cascade semiconductor laser 11a includes a first recess 23a and a second recess 23b which separate the first mesa 19a and the second mesa 19b from the semiconductor mesa 19c in the first region 21a, respectively. The first and second recess 23a and 23b extend in the direction of the first axis Ax1, and are connected to the recess 23 in each of the second and third regions 21b and 21c.

The first semiconductor film 15 includes an eleventh portion 15m and a twelfth portion 15n, which are disposed on the seventh side face 19p of the first mesa 19a and the eighth side face 19q of the second mesa 19b, respectively. In addition, the first semiconductor film 15 includes a ninth portion 15i and a tenth portion 15j, which are disposed on the side faces of the semiconductor mesa 19c, and includes the seventh portion 15g and the eighth portion 15h, which are disposed on the third area 17f. As described above, the surfaces of the first and second recesses 23a and 23b are covered with the first semiconductor film 15. The eleventh and twelfth portions 15m and 15n make contact with the seventh side face 19p of the first mesa 19a and the eighth side face 19q of the second mesa 19b, respectively. The eleventh and twelfth portions 15m and 15n extend in the direction of the first axis Ax1. In the present embodiment, the seventh and eighth side faces 19p and 19q are connected to the first and second side faces 19d and 19e, respectively. The eleventh and twelfth portions 15m and 15n are connected to the second and third portions 15b and 15c, respectively. The seventh and eighth portions 15g and 15h are connected to the first portion 15a. The ninth and tenth portions 15i and 15j are connected to both side edges of the fourth portion 15d. The first semiconductor film 15 extending on the surfaces of the first and second recesses 23a and 23b can reinforce the first portion 15a.

The fifth and sixth side faces 19m and 19n of the semiconductor mesa 19c are covered with the first semiconductor film 15, and the first semiconductor film 15 on the fifth and sixth side faces 19m and 19n of the semiconductor mesa 19c and the semiconductor mesa 19c constitutes the waveguide mesa 33 on the third area 17f.

In the quantum cascade semiconductor laser 11a, the first semiconductor film 15 continuously extends on the end face 19f, the fifth side face 19m, and the sixth side face 19n of the semiconductor mesa 19c. The first semiconductor film 15 on the fifth and sixth side faces 19m and 19n of the semiconductor mesa 19c are simultaneously formed in the same fabrication step as that of the first semiconductor film 15 on the end face 19f of the semiconductor mesa 19c. The first semiconductor film 15 on the side faces of the semiconductor mesa 19c serves as a current blocking layer, which confines current into the semiconductor mesa 19c. Each of the first, second, and third regions 21a, 21b, and 21c of the laser structure 13 includes the first and second mesas 19a and 19b. Arranging the first mesa 19a and the second mesa 19b in the second and third regions 21b and 21c in addition to the first region 21a allows forming the laser structure 13 by etching a limited area defining the recess 23 and the first and second recesses 23a and 23b. Etching the limited area leads to increase in etching rate, makes it possible to provide the semiconductor mesa 19c with a large height that the quantum cascade semiconductor laser needs, shortens the etching time and improves the productivity.

### Third Embodiment

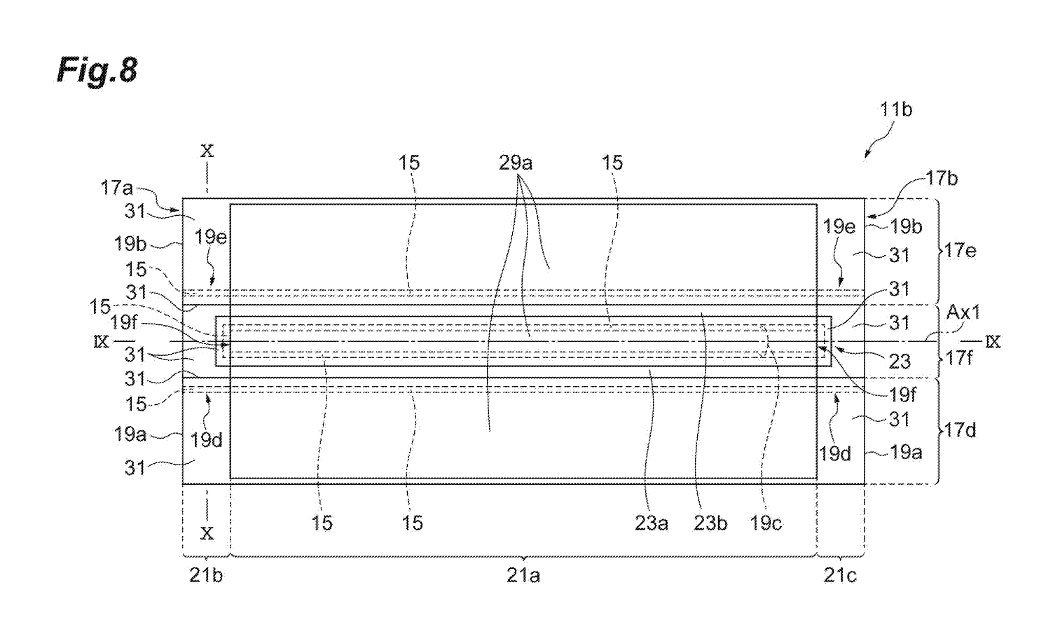

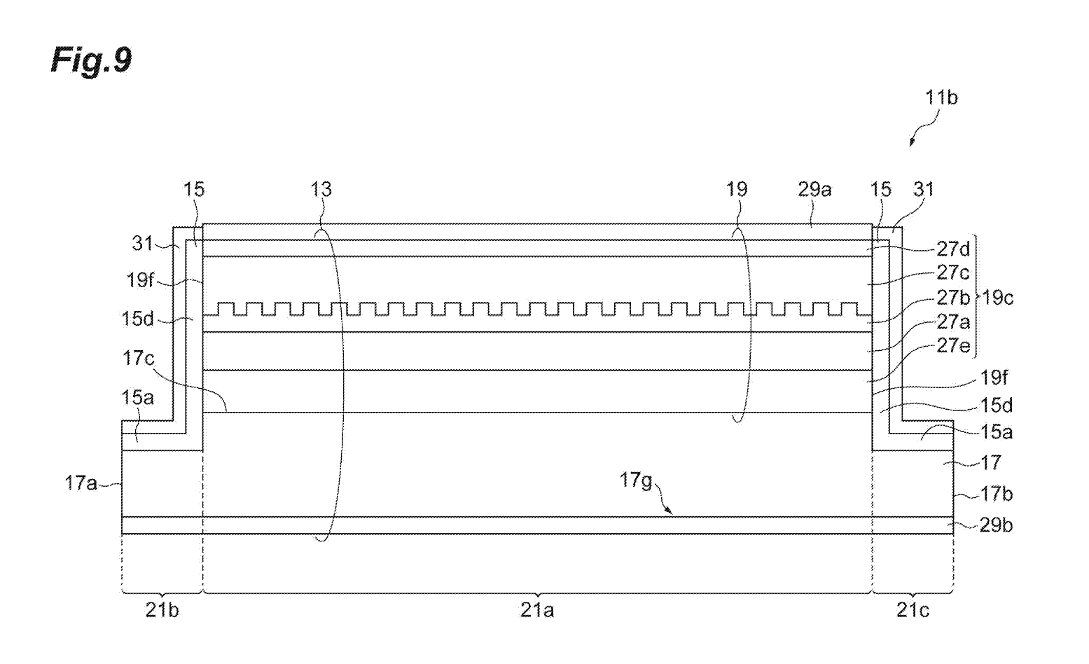

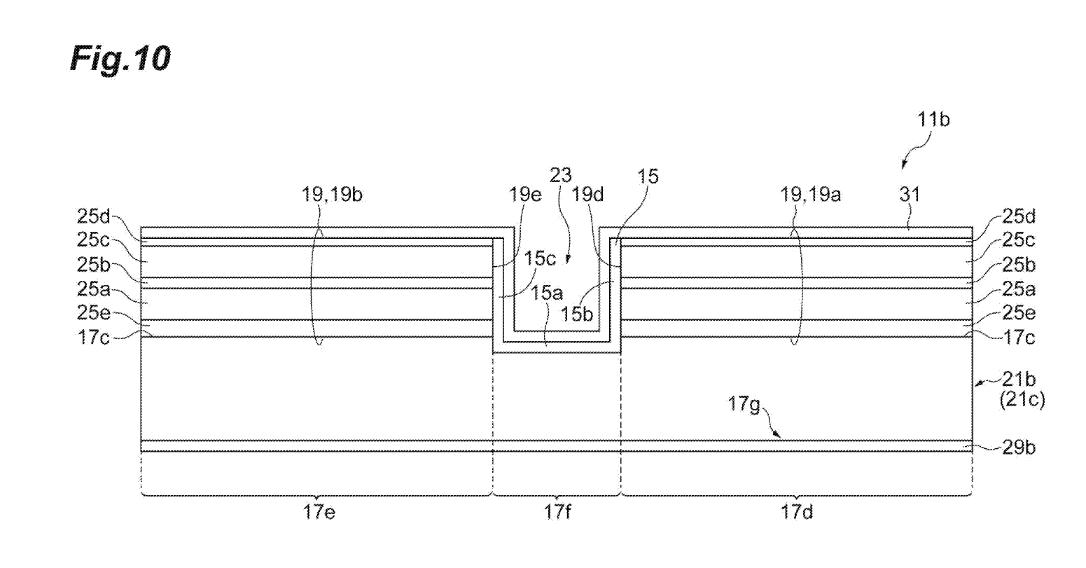

FIG. 8 is a plan view showing a quantum cascade semiconductor laser according to the embodiment. FIG. 9 is a cross sectional view taken along line IX-IX shown in FIG. 8. FIG. 10 is a cross sectional view taken along line X-X shown in FIG. 8. With reference to FIGS. 8 to 10, the quantum cascade laser 11b according to the third embodiment will be described below. In the second region 21b of the quantum cascade laser 11b, the insulating film 31 is formed on the first semiconductor film 15, which is on the third area 17f, the end face 19f of the semiconductor mesa 19c, the first side face 19d of the first mesa 19a, and the second side face 19e of the second mesa 19b. The quantum cascade semiconductor laser 11b is different from the quantum cascade semiconductor laser 11a in terms of the insulating film 31. If necessary, in the third region 21c, the insulating film 31 can be disposed on the first semiconductor film 15, which is on the third area 17f, the end face 19f of the semiconductor mesa 19c, the first side face 19d of the first mesa 19a, and the second side face 19e of the second mesa 19b. The insulating films 31 in the second region 21b and the third region 21c may be formed simultaneously in the same process step as that of the insulating film 31 provided between the first electrode 29a and the first semiconductor film 15 in the first region 21a.

The addition of the insulating film 31 covering the first semiconductor film 15 allows the film 31, made of material used as a passivation film, to cover the first semiconductor film 15, and the insulating film 31 can reduce the occurrence of peeling and/or cracking of the first semiconductor film 15 that may be caused in forming semiconductor chips, for example, by cleaving.

This covering is less likely to cause breakage of the first semiconductor film 15 on the end face 19f of the semiconductor mesa 19c.

When necessary, the insulating film 31 is disposed so as to extend from the first side face 19d of the first mesa 19a and the second side face 19e of the second mesa 19b onto the top faces of the first and second mesas 19a and 19b, and this extension can reinforce the first semiconductor film 15 on the first side face 19d of the first mesa 19a and the second side face 19e of the second mesa 19b in terms of the mechanical strength. The structures according to the other embodiments can also use the insulating film 31, which is disposed over the first semiconductor film 15, in the present embodiment.

### Fourth Embodiment

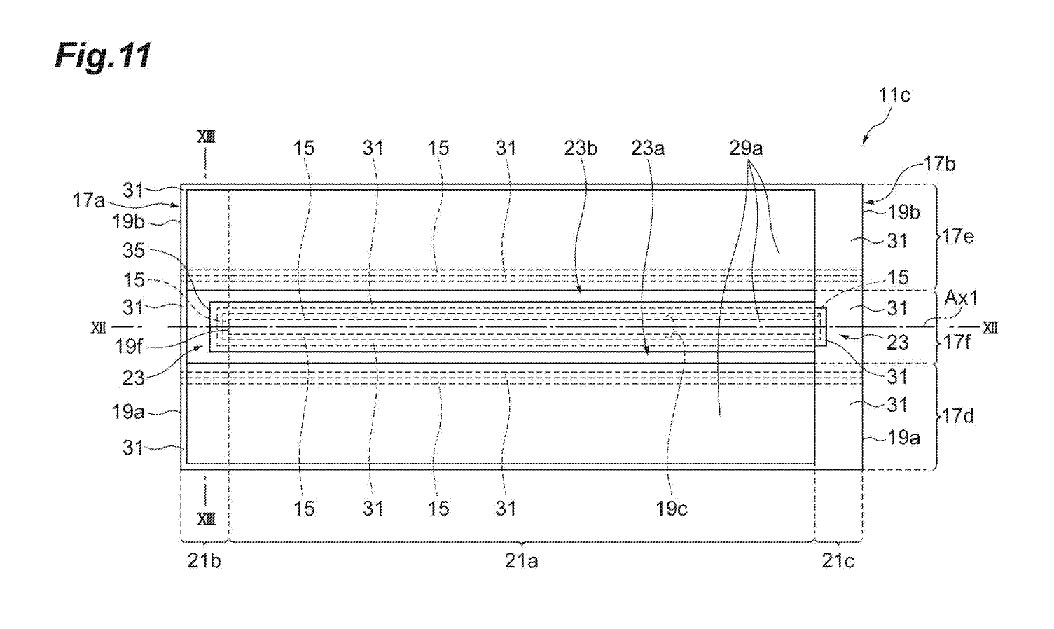

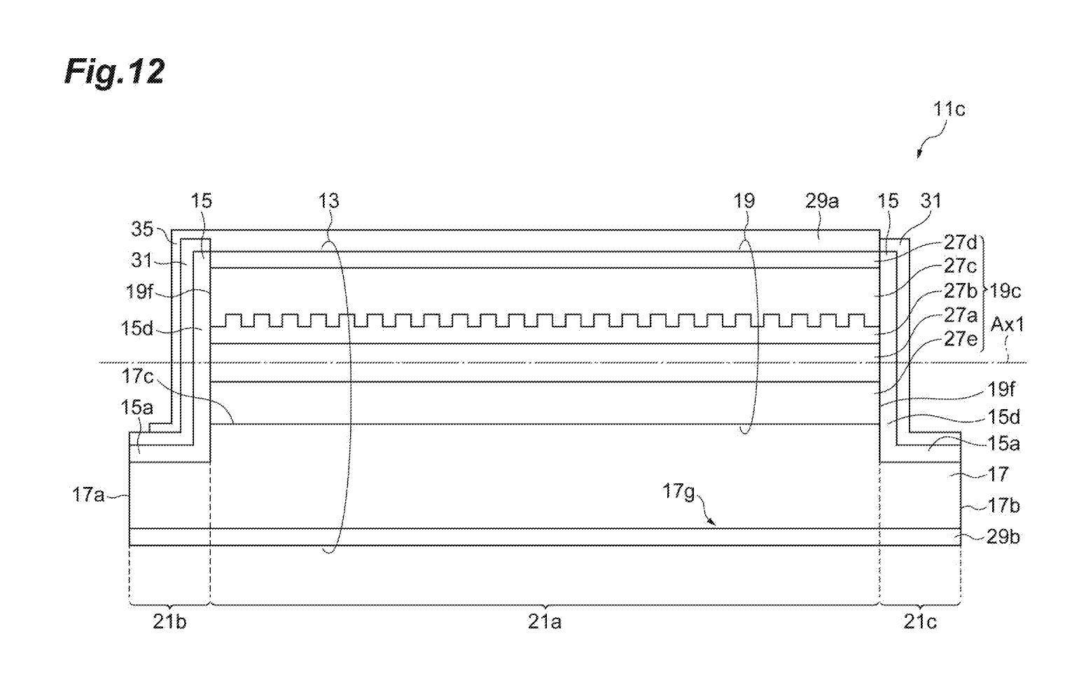

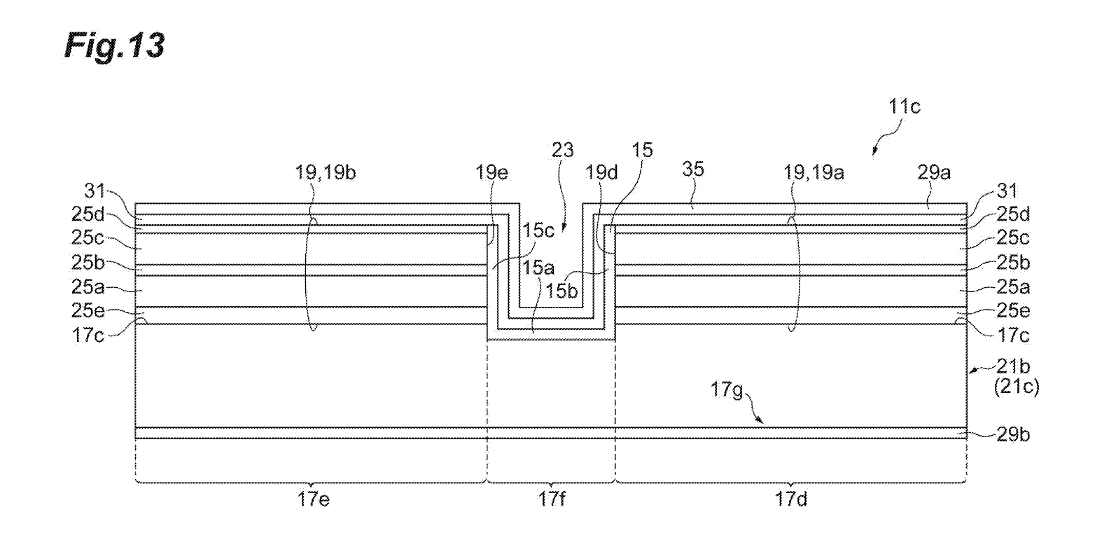

FIG. 11 is a plan view showing the quantum cascade semiconductor laser according to the embodiment. FIG. 12 is a cross-sectional view taken along line XII-XII shown in FIG. 11. FIG. 13 is a cross-sectional view taken along line XIII-XIII shown in FIG. 11. Referring to FIGS. 11 to 13, the quantum cascade laser 11c may further include a reflective film 35. The reflective film 35 is disposed on the first semiconductor film 15 that is on the end face 19f of the semiconductor mesa 19c. The addition of the reflective film 35 allows the quantum cascade laser 11c to provide a high optical reflectivity with the end face 19f of the semiconductor mesa 19c. The reflective film 35 may include, for example, a metal layer, and preferably, the metal layer includes an Au film. For example, a gold film has a reflectivity of 90 percent or more in the mid-infrared wavelength range (3 to 20 micrometers). Such a reflectance is provided by the gold film of 10 nm or more, and the gold reflective film may have a thickness of, for example, 50 to 100 micrometers. The material of the reflective film 35 is not limited to gold, but may be made of a gold-based metal, such as Ti/Au, Ti/Pt/Au, or Ge/Au. In the second region 21b, the reflective film 35 has an edge apart from the upper edge of the first end face 17a, while the first semiconductor film 15 and the insulating film 31 reach the upper edge of the first end face 17a. In the present embodiment, the first electrode 29a extends from the upper face of the semiconductor mesa 19c onto the end face 19f, and this extension provides the reflective film 35 on the end face 19f of the semiconductor mesa 19c. The reflective film 35 is made of the same material as that formed as the first electrode 29a, for example Ti/Au, Ti/Pt/Au, Ge/Au, and the reflective film 35 and the first electrode 29a are simultaneously formed in the same process step. If necessary, the reflective film 35 may include a material different from that of the first electrode 29a.

A reflectance of more than 90% can provide a significant reduction in the threshold current. When necessary, the insulating film 31 is provided between the reflective film 35 and the first semiconductor film 15 as in the present embodiment. When possible, the reflective film 35 can be disposed on the first semiconductor film 15 without the insulating film 31 provided on the first semiconductor film 15 located on the end face 19f of the semiconductor mesa 19c. If necessary, such a reflective film made of metal can also be disposed on the end face 19f of the semiconductor mesa 19c in the third region 21c.

If necessary, the quantum cascade semiconductor laser 11c can emit light from either the second region 21b or the third region 21c. The structures of the other embodiments can also provide the end face 19f of the semiconductor mesa 19c, which is used in the present embodiment, with the reflective film 35.

The quantum cascade laser according to the embodiments as above is provided with a structure that prevent the defects from reaching the inner region of the quantum cascade laser.

Having described and illustrated the principle of the invention in a preferred embodiment thereof, it is appreciated by those having skill in the art that the invention can be modified in arrangement and detail without departing from such principles. We therefore claim all modifications and variations coining within the spirit and scope of the following claims.

What is claimed is:

1. A quantum cascade laser comprising:
a laser structure including a substrate and a semiconductor laminate region, the substrate having a principal surface that includes a first area, a second area, and a third area that extend in a direction of a first axis, the third area being disposed between the first area and the second area, the substrate having a first end face and a second end face which are arranged in the direction of the first axis, the semiconductor laminate region having a first mesa, a second mesa, and a semiconductor mesa which are arranged on the first area, the second area, and the third area, respectively; and
a first semiconductor film disposed on the third area of the substrate, a side face of the first mesa, a side face of the second mesa, and an end face of the semiconductor mesa,
wherein the laser structure includes a first region and a second region arranged in the direction of the first axis, the first region including the semiconductor mesa, and the second region including the first mesa and the second mesa,
the semiconductor mesa includes a core region, and
the second region of the laser structure includes a recess defined by the third area, the side face of the first mesa, and the side face of the second mesa.

2. The quantum cascade laser according to claim 1, wherein the first region includes the first mesa and the second mesa,
the semiconductor mesa is disposed between the first mesa and the second mesa, and
in the first region, the semiconductor mesa is separated from the side face of the first mesa and the side face of the second mesa.

3. The quantum cascade laser according to claim 1, further comprising an insulating film disposed on the first semiconductor film.

4. The quantum cascade laser according to claim 1, further comprising a reflective film disposed on the first semiconductor film disposed on the end face of the semiconductor mesa.

5. The quantum cascade laser according to claim 4, wherein the reflective film includes gold.

6. The quantum cascade laser according to claim 4, further comprising an electrode on the first region, the electrode including the same material as that of the reflective film.

7. The quantum cascade laser according to claim 1, wherein the first semiconductor film is disposed on side faces of the semiconductor mesa,
the semiconductor mesa and the first semiconductor film constitute a waveguide mesa,
the laser structure has a first recess and a second recess in the first region,
the first recess separates the waveguide mesa from the first mesa, and
the second recess separates the waveguide mesa from the second mesa.
